(19) United States
(12) Patent Application Publication
(10) Pub. No.: US 2019/0053386 A1
(43) Pub. Date: Feb. 14, 2019

(54) RESIN MULTILAYER SUBSTRATE MANUFACTURING METHOD

(71) Applicant: Murata Manufacturing Co., Ltd., Nagaokakyo-shi (JP)

(72) Inventors: Masaki KAWATA, Nagaokakyo-shi (JP); Yuki ITO, Nagaokakyo-shi (JP)

(21) Appl. No.: 16/161,118

(22) Filed: Oct. 16, 2018

Related U.S. Application Data
(63) Continuation of application No. PCT/JP2017/014528, filed on Apr. 7, 2017.

(30) Foreign Application Priority Data
Apr. 26, 2016 (JP) 2016-087973

(51) Int. Cl. H05K 3/46

(52) U.S. Cl. CPC H05K 3/4655; H05K 3/4697; H05K 3/4682; H05K 1/0313; H05K 2203/068; H05K 2201/0141; H05K 2201/0154; H05K 2201/0129

(57) ABSTRACT

A resin multilayer substrate manufacturing method includes arranging a first sheet including a thermoplastic resin as a main material, arranging one or more second sheets each including a first opening and a thermoplastic resin as a main material to be stacked on the first sheet, applying heat and pressure to a multilayer body including the first sheet and the one or more second sheets in a state in which a block, with a higher rigidity than the thermoplastic resin, is inside a space formed by the first opening of one second sheet or by a series of first openings of two or more second sheets, and removing the block.

### CROSS REFERENCE TO RELATED APPLICATIONS

This application claims the benefit of priority to Japanese Patent Application No. 2016-087973 filed on Apr. 26, 2016 and is a Continuation Application of PCT Application No. PCT/JP2017/014528 filed on Apr. 7, 2017. The entire contents of each application are hereby incorporated herein by reference.

### BACKGROUND OF THE INVENTION

### 1. Field of the Invention

The present invention relates to a method for manufacturing a resin multilayer substrate.

### 2. Description of the Related Art

Japanese Unexamined Patent Application Publication No. 2006-156908 discloses an example of a method for manufacturing a printed substrate. Japanese Unexamined Patent Application Publication No. 2006-156908 discloses that in order to ensure that heating and pressing are sufficiently performed in a case in which the number of resin sheets that are stacked differs depending on the location, a sheet-shaped cushioning material is interposed between a pressing plate and a resin sheet, a protrusion is provided on the pressing plate, and heating and pressing are performed such that the protrusion enters an opening in the resin sheet.

In order to perform the manufacturing method disclosed in Japanese Unexamined Patent Application Publication No. 2006-156908, it is necessary to prepare a pressing plate on which a protrusion is provided at the appropriate position and that has the appropriate size for each product. However, preparation of different pressing plates for different products results in a significant increase in cost.

### SUMMARY OF THE INVENTION

Preferred embodiments of the present invention provide manufacturing methods with which heating and pressing are able to be normally performed and with which a resin multilayer substrate in which a desired recess is appropriately provided is able to be obtained without incurring a significant increase in cost.

A resin multilayer substrate manufacturing method according to a preferred embodiment of the present invention includes a step of arranging a first sheet that includes a thermoplastic resin as a main material; a step of arranging one or more second sheets, which each include a first opening and a thermoplastic resin as a main material, so as to be stacked on the first sheet; a thermocompression bonding step of applying heat and pressure to a multilayer body formed so as to include the first sheet and the one or more second sheets in a state in which a block, which has a higher rigidity than the thermoplastic resin, is inside a space formed by the first opening of one second sheet or by a series of first openings of two or more second sheets; and a step of removing the block after the thermocompression bonding step.

According to a preferred embodiment of the present invention, heating and pressing are performed in a state in which a block, which has a higher rigidity than a thermoplastic resin, is inside a space formed by the first opening of one second sheet or by a series of first openings of two or more second sheets, and therefore heating and pressing are able to be normally performed and a resin multilayer substrate is able to be obtained in which a desired recess is appropriately provided without incurring a significant increase in cost.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a flowchart of a resin multilayer substrate manufacturing method of preferred embodiment 1 of the present invention.

FIG. 2 is an explanatory diagram of a first step of the resin multilayer substrate manufacturing method of preferred embodiment 1 of the present invention.

FIG. 3 is an explanatory diagram of a second step of the resin multilayer substrate manufacturing method of preferred embodiment 1 of the present invention.

FIG. 4 is an explanatory diagram of a third step of the resin multilayer substrate manufacturing method of preferred embodiment 1 of the present invention.

FIG. 5 is an explanatory diagram of a situation in which a block is temporarily pressure bonded to the surface of a third sheet in the resin multilayer substrate manufacturing method of preferred embodiment 1 of the present invention.

FIG. 6 is a sectional view of a situation in which a block has been temporarily pressure bonded to the surface of a third sheet in the resin multilayer substrate manufacturing method of preferred embodiment 1 of the present invention.

FIG. 7 is an explanatory diagram of a fourth step of the resin multilayer substrate manufacturing method of preferred embodiment 1 of the present invention.

FIG. 8 is a sectional view of a multilayer body obtained partway through the resin multilayer substrate manufacturing method of preferred embodiment 1 of the present invention.

FIG. 9 is an explanatory diagram of a fifth step of the resin multilayer substrate manufacturing method of preferred embodiment 1 of the present invention.

FIG. 10 is an explanatory diagram of a sixth step of the resin multilayer substrate manufacturing method of preferred embodiment 1 of the present invention.

FIG. 11 is an explanatory diagram of a seventh step of the resin multilayer substrate manufacturing method of preferred embodiment 1 of the present invention.

FIG. 12 is an explanatory diagram of an eighth step of the resin multilayer substrate manufacturing method of preferred embodiment 1 of the present invention.

FIG. 13 is an explanatory diagram of a first step of a resin multilayer substrate manufacturing method of preferred embodiment 2 of the present invention.

FIG. 14 is an explanatory diagram of a second step of the resin multilayer substrate manufacturing method of preferred embodiment 2 of the present invention.

FIG. 15 is an explanatory diagram of a third step of the resin multilayer substrate manufacturing method of preferred embodiment 2 of the present invention.

FIG. 16 is an explanatory diagram of a fourth step of the resin multilayer substrate manufacturing method of preferred embodiment 2 of the present invention.

FIG. 17 is an explanatory diagram of a first step of a resin multilayer substrate manufacturing method of preferred embodiment 3 of the present invention.

FIG. 18 is a sectional view of a situation in which a block has been temporarily pressure bonded to the surface of a first sheet in the resin multilayer substrate manufacturing method of preferred embodiment 3 of the present invention.

FIG. 19 is an explanatory diagram of a second step of the resin multilayer substrate manufacturing method of preferred embodiment 3 of the present invention.

FIG. 20 is an explanatory diagram of a third step of the resin multilayer substrate manufacturing method of preferred embodiment 3 of the present invention.

FIG. 21 is an explanatory diagram of a fourth step of the resin multilayer substrate manufacturing method of preferred embodiment 3 of the present invention.

FIG. 22 is an explanatory diagram of a fifth step of the resin multilayer substrate manufacturing method of preferred embodiment 3 of the present invention.

### DETAILED DESCRIPTION OF THE PREFERRED EMBODIMENTS

Preferred embodiments of the present invention will be described below with reference to the drawings. The dimensional ratios depicted in the drawings do not necessarily accurately depict the actual dimensional ratios, and the dimensional ratios in the drawings may be depicted in an exaggerated manner for convenience of explanation. In the following description, when reference is made to the concepts of above and below, the meanings of these terms are not limited to meaning absolutely above and below, and may mean relatively above and below within the illustrated states.

### Preferred Embodiment 1

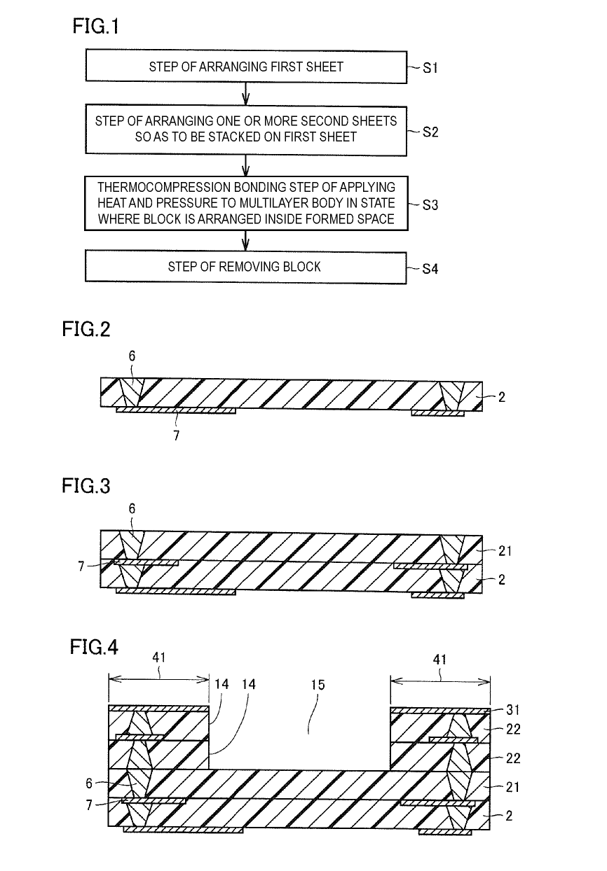

A resin multilayer substrate manufacturing method of preferred embodiment 1 of the present invention will be described with reference to FIGS. 1 to 12. Firstly, FIG. 1 illustrates a flowchart of the resin multilayer substrate manufacturing method of the present preferred embodiment.

The resin multilayer substrate manufacturing method of the present preferred embodiment includes a step S1 of arranging a first sheet that includes a thermoplastic resin as a main material; a step S2 of arranging one or more second sheets, which each include a first opening and a thermoplastic resin as a main material, so as to be stacked on the first sheet; a thermocompression bonding step S3 of applying heat and pressure to a multilayer body formed so as to include the first sheet and the one or more second sheets in a state in which a block that has a higher rigidity than the thermoplastic resin is inside a space formed by the first opening of one second sheet or by a series of the first openings of two or more second sheets; and a step S4 of removing the block after the thermocompression bonding step S3.

The individual steps of the resin multilayer substrate manufacturing method will be described in detail hereafter. The description hereafter includes not only steps illustrated in the flowchart in FIG. 1 but also steps not illustrated in the flowchart in FIG. 1. An example of the resin multilayer substrate manufacturing method is described below. All of the steps described here are not necessarily essential.

A resin multilayer substrate is manufactured by stacking a plurality of resin sheets including a thermoplastic resin as a main material on top of one another and then thermocompression bonding the stacked plurality of resin sheets in order to integrate the resin sheets with each other. First, as illustrated in FIG. 2, a resin sheet 2 including a thermoplastic resin as a main material is prepared. A liquid crystal polymer (LCP), a thermoplastic polyimide, or other suitable material may preferably be used as the thermoplastic resin, for example. The resin sheet 2 may include a conductor pattern 7 on both surfaces or one surface thereof. The resin sheet 2 may include conductor vias 6 that define and function as interlayer connection conductors. The conductor vias 6 penetrate through the resin sheet 2 in a thickness direction of the resin sheet 2. In order to obtain the resin sheet 2 as illustrated in FIG. 2, for example, a conductor pattern may be formed by adhering a conductor foil to the entirety or substantially the entirety of one surface of a resin sheet, that is, preparing a resin sheet including a conductor foil and then patterning the conductor pattern using a known technique. The conductor foil may preferably be a copper foil, for example. In the case in which the conductor vias 6 are necessary, the conductor vias 6 may be formed by providing through holes in the resin sheet using a known technique, such as laser processing, for example, filling the through holes with a conductive paste, and solidifying (metallizing) the conductive paste.

In the step S1, as illustrated in FIG. 3, a first sheet 21 is arranged. The first sheet 21 includes a thermoplastic resin as a main material. In the example illustrated in FIG. 3, the first sheet 21 is arranged so as to be stacked on the upper surface of the resin sheet 2. This preferred embodiment is not limited to only one resin sheet 2 being arranged on the lower side of the first sheet 21, and a plurality of resin sheets 2 may instead be arranged on the lower side of the first sheet 21 in a stacked manner. Alternatively, no resin sheet 2 may be arranged on the lower side of the first sheet 21. In the case in which there is no resin sheet 2 on the lower side of the first sheet 21, the first sheet 21 may define and function as the lowermost layer. The first sheet 21 may include a conductor pattern 7 on both surfaces or one surface thereof. The first sheet 21 may include conductor vias 6. The conductor vias 6 penetrate through the first sheet 21 in a thickness direction of the first sheet 21.

In the step S2, as illustrated in FIG. 4, one or more second sheets 22, which each include a thermoplastic resin as a main material, are arranged so as to be stacked on the first sheet 21. Each first sheet 21 includes a first opening 14. A space 15 is formed by the first opening 14 of one second sheet 22 or by a series of the first openings 14 of two or more second sheets 22. Each first opening 14 preferably has a rectangular or substantially rectangular shape when seen from above in the drawings, for example. In the example illustrated in FIG. 4, the space 15 is formed by a series of the first openings 14 of two second sheets 22. The space 15 may preferably be a rectangular or substantially parallelepiped shaped space, for example. When the step S2 is complete, the upper surface of the uppermost second sheet 22 among the one or more second sheets includes a first region 41 that is covered by a first conductor foil 31.

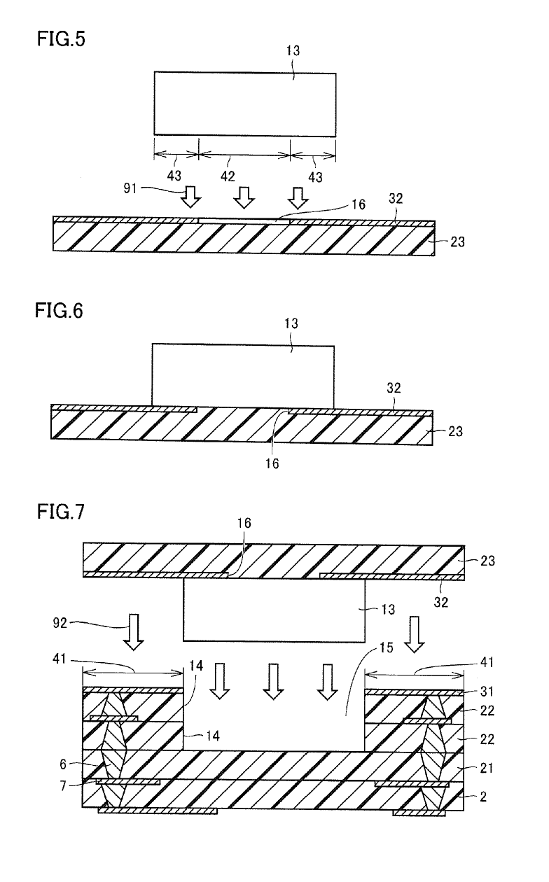

As illustrated in FIG. 5, a block 13 is temporarily pressure bonded to a surface of a third sheet 23. For example, a stainless steel block may preferably be used as the block 13. The block 13 may preferably be formed of any of a variety of metals such as Cu, Al, or other suitable metal, or may be formed of an alloy of such a metal, for example. The block 13 may be formed of a resin such as polyimide, PEEK, or other suitable resin, for example. A second conductor foil 32 is arranged on at least a portion of the upper surface of the third sheet 23. The block 13 is placed on the upper surface of the third sheet 23 as indicated by arrows 91. In the example illustrated in FIG. 5, the second conductor foil 32 includes a second opening 16. The block 13 may be positioned with respect to the third sheet 23 and temporarily pressure bonded to the third sheet 23 in a state of being affixed by an adhesive sheet, which is not illustrated. In the example illustrated in FIG. 5, the lower surface of the block 13 includes a second region 42 and a third region 43. The second region 42 is a region that corresponds to the second opening 16, and the third region 43 is a region located around the periphery of the second region 42. The third region 43 contacts the second conductor foil 32. Heat or pressure or both heat and pressure may be used to perform the temporary pressure bonding. The situation illustrated in FIG. 6 is achieved as a result of temporarily pressure bonding the block 13 to the surface of the third sheet 23.

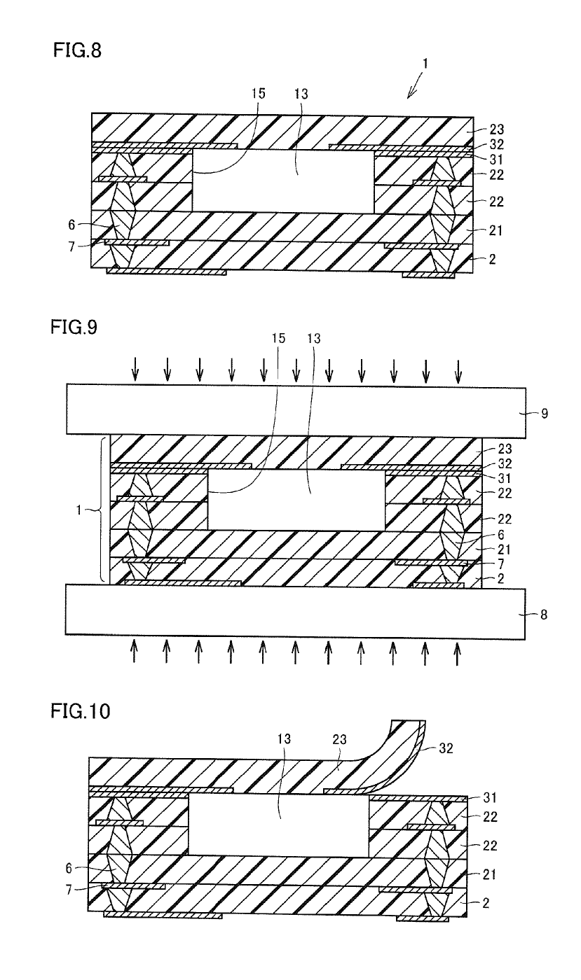

As illustrated in FIG. 7, the third sheet 23, to which the block 13 has been temporarily pressure bonded, is moved toward the multilayer body including the first sheet 21 and the second sheets 22, for example, that is, the multilayer body illustrated in FIG. 4 from above as indicated by the arrows 92 in a state in which the block 13 faces downward. At this time, the block 13 is aligned with the space 15. The third sheet 23 is stacked on the upper side of the second sheets 22 such that the block 13 enters the inside of the space 15. Thus, a multilayer body 1 illustrated in FIG. 8 is obtained.

As the thermocompression bonding step S3, heat and pressure are applied to the multilayer body 1, which is formed so as to include the first sheet 21 and the one or more second sheets 22, in a state in which the block 13, which has a higher rigidity than the thermoplastic resin, is arranged inside the space 15. “Having a higher rigidity than the thermoplastic resin” means having a larger Young's modulus than the thermoplastic resin within a certain temperature range. This step is to integrate the multilayer body 1, and is also called a “permanent pressure bonding step”. In the thermocompression bonding step S3, for example, as illustrated in FIG. 9, the multilayer body 1 is sandwiched between a lower pressing plate 8 and an upper pressing plate 9 and subjected to pressing while being heated. As a result, pressure bonding occurs at portions inside the multilayer body 1 at which thermoplastic resin portions contact each other, and substantially all of the portions of the multilayer body 1 are integrated with each other. In FIG. 9, the multilayer body 1 is directly sandwiched between the lower pressing plate 8 and the upper pressing plate 9, but a cushioning material may instead be interposed between the lower pressing plate 8 and the multilayer body 1, between the upper pressing plate 9 and the multilayer body 1, or at both of these locations. In addition, it is preferable that the block 13 is composed of a material that substantially does not flow at the temperature used when performing the thermocompression bonding. In this case, since the rigidity of the block 13 is able to be maintained under the condition of the temperature used when performing the thermocompression bonding (for example, about 260° C. to about 300° C.), a resin multilayer substrate 101 including a recess 27 having a shape that is stable and satisfactory is able to be obtained.

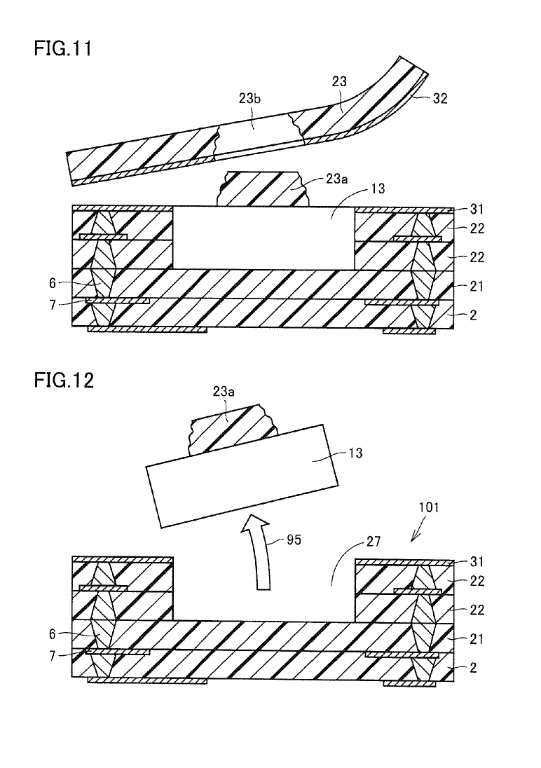

As illustrated in FIG. 10, the third sheet 23 is peeled off. Even when heat and pressure are applied at the interface at which the conductor foils contact each other, thermocompression bonding does not occur. In other words, the conductor foils are not bonded to each other. Since thermocompression bonding does not occur between the second conductor foil 32 arranged on the lower surface of the third sheet 23 and the first conductor foil 31 arranged on the upper surface of the uppermost second sheet 22, the third sheet 23 is able to be easily peeled off. There is a possibility that the third sheet 23 will pressure bond to the block 13 in the region at which the block 13 and the third sheet 23 contact each other without the second conductor foil 32 interposed therebetween, but even if this occurs, the surface area that is pressure bonded is limited, and therefore the third sheet 23 is able to be peeled off as illustrated in FIG. 11. In the example illustrated in FIG. 11, a portion of the third sheet 23 remains adhered to the upper surface of the block 13 as a remaining portion 23a, and a missing portion 23b is formed in the third sheet 23. The missing portion 23 may have the form of a through hole or a cavity that does not penetrate all the way through. The example illustrated in FIG. 11 is merely an example, and generation of the remaining portion 23a is not limited to this example. When the third sheet 23 is peeled off, the entirety or substantially the entirety of the third sheet 23 may be peeled off without any remaining portion remaining on the upper surface of the block 13.

In the step S4, the block 13 is removed as illustrated in FIG. 12 after the thermocompression bonding step S3. Thus, the resin multilayer substrate 101 including the recess 27 is obtained. The method of removing the block 13 in the step S4 may be a method in which some kind of adhesive sheet is adhered to the upper surface of the block 13 and the block 13 is pulled out, a method in which the block 13 is sucked by applying a negative pressure thereto, or a method in which the block 13 is removed by causing the resin multilayer substrate 101 to deform. In the case in which the block 13 has a higher rigidity than the resin multilayer substrate 101, the block 13 is able to be removed by causing the resin multilayer substrate 101 to appropriately deform. The method of removing the block 13 in the step S4 may be a method in which a through hole (not illustrated) is provided in the resin multilayer substrate 101 so as to penetrate through to the bottom surface of the recess 27 and an element is inserted into the through hole from the opposite side in order to push the block 13 out.

In the present preferred embodiment, the resin multilayer substrate 101 including the recess 27 is able to be obtained. Since the thermocompression bonding step S3 is performed in a state in which the block 13, which has a higher rigidity than the thermoplastic resin, is arranged inside the space 15, heating and pressing is able to be normally performed and the resin multilayer substrate 101 is able to be obtained in which a desired recess is appropriately provided. The metal molds used in the thermocompression bonding step S3 may be flat as illustrated by the lower pressing plate 8 and the upper pressing plate 9, and therefore, there is no need to prepare a large number of different metal molds to match the shape of the resin multilayer substrate 101. Therefore, a significant increase in cost is not incurred.

As illustrated in the present preferred embodiment, after the step of temporarily pressure bonding the block 13 to the surface of the third sheet 23 (refer to FIG. 5 and FIG. 6) and the step S2 of arranging and stacking the one or more second sheets 22 and prior to the thermocompression bonding step S3, it is preferable that the method further include a step of stacking the third sheet 23 on the upper side of the one or more second sheets 22 (refer to FIG. 7) such that the block 13, which is temporarily pressure bonded to the third sheet 23, is below the third sheet 23 and enters the inside of the space 15, and a step of removing the third sheet 23 (refer to FIG. 10 and FIG. 11). By using this method, the block 13 is stably affixed, and the block 13 is able to be easily arranged inside the space 15.

As illustrated in the present preferred embodiment, when the step S2 of arranging one or more second sheets 22 so as to be stacked on the first sheet 21 is complete (refer to FIG. 4), it is preferable that the upper surface of the uppermost second sheet 22 among the one or more second sheets 22 include the first region 41 that is covered by the first conductor foil 31 and that at least the region of the third sheet 23 that faces the first region 41 be covered by the second conductor foil 32 in the step of stacking the third sheet 23 (refer to FIG. 7). As a result of using this method, the first conductor foil 31 and the second conductor foil 32 contact each other at the interface between the uppermost second sheet 22 and the third sheet 23, and therefore, the third sheet 23 is able to be prevented from being pressure bonded to the second sheet 22 when the thermocompression bonding step S3 is performed. Therefore, the third sheet 23 is able to be easily removed when the step of removing the third sheet 23 is performed later (refer to FIG. 10 and FIG. 11).

As illustrated in in the present preferred embodiment, it is preferable that the second conductor foil 32 include the second opening 16 and that the block 13 include the second region 42 that is temporarily pressure bonded to the third sheet 23 via the second opening 16 (refer to FIG. 5) and the third region 43 that contacts the second conductor foil 32 around the periphery of the second opening 16. As a result of using this method, the third sheet 23 to which the block 13 has been temporarily pressure bonded maintains a state of not being pressure bonded to the third region 43 while being pressure bonded to and holding the block 13 in the second region 42. Thus, it is possible to limit the region in which the block 13 is pressure bonded to the third sheet 23, and therefore, the connection between the block 13 and the third sheet 23 is easily severed and the third sheet 23 is able to be easily removed when the step of removing the third sheet 23 (refer to FIG. 10 and FIG. 11) is performed later.

### Preferred Embodiment 2

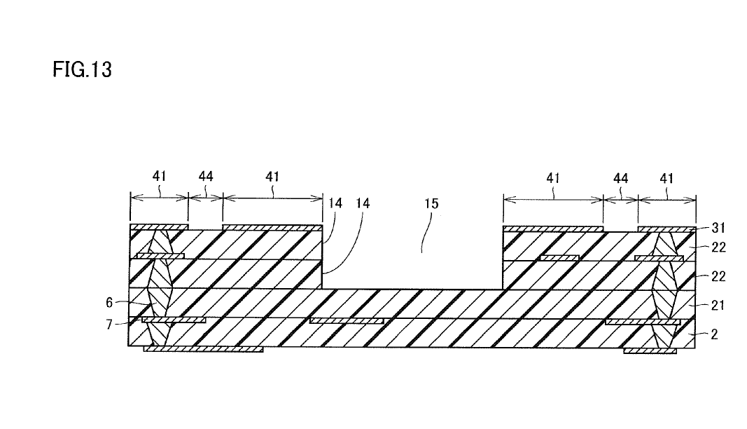

A resin multilayer substrate manufacturing method of preferred embodiment 2 of the present invention will be described with reference to FIGS. 13 to 16. The basic flow of the resin multilayer substrate manufacturing method of the present preferred embodiment is the same or substantially the same as that of the manufacturing method described in the preferred embodiment 1, but the manufacturing method of the present preferred embodiment differs with respect to the following points.

In the present preferred embodiment, as illustrated in FIG. 13, the upper surface of the uppermost second sheet 22 among the one or more second sheets 22 includes a fourth region 44 that is not covered by a conductor foil and is exposed.

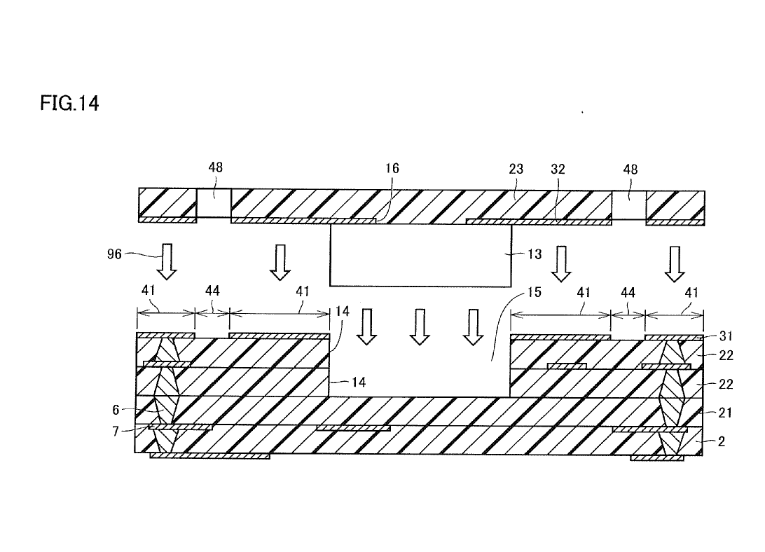

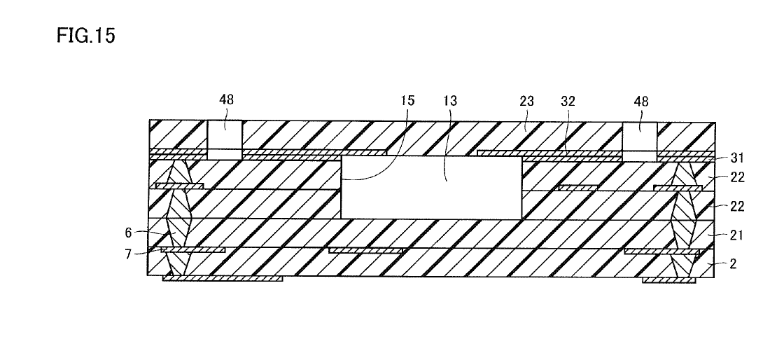

In the present preferred embodiment, in the step of stacking the third sheet 23, as illustrated in FIG. 14, the upper surface of the uppermost second sheet 22 among the one or more second sheets 22 includes the fourth region 44 that is not covered by a conductor foil and is exposed, and a recess or a through hole is formed in a region of the third sheet 23 that faces the fourth region 44. In this case, a through hole 48 is provided as an example of “a recess or through hole”. A recess may be provided in this region, instead of the through hole 48.

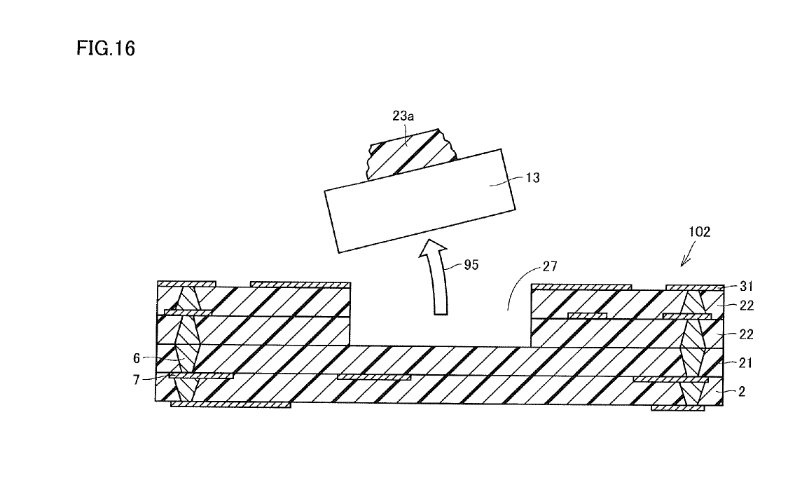

FIG. 15 illustrates a state in which the step of stacking the third sheet 23 is complete. In FIG. 15, a multilayer body is formed. In this state, the thermocompression bonding step S3 is performed. In the thermocompression bonding step S3, for example, the multilayer body is sandwiched between the lower pressing plate 8 and the upper pressing plate 9 and subjected to pressing while being heated.

In addition, as the step S4, the block 13 is removed as illustrated in FIG. 16 after the thermocompression bonding step S3. Thus, a resin multilayer substrate 102 including a recess 27 is able to be obtained. The details of the method of removing the block 13 in the step S4 are the same or substantially the same as described in preferred embodiment 1.

In the present preferred embodiment, the upper surface of the second sheet 22 includes the fourth region 44 that is not covered by a conductor foil and is exposed, and a recess or through hole is formed in a region of the third sheet 23 that faces the fourth region 44, and therefore a state is able to be achieved in which there is no surface that contacts the upper surface of the uppermost second sheet 22 in the fourth region 44 and in which the resin exposed in the fourth region 44 does not contact any other member until the end of the thermocompression bonding step S3. By using this method, the thermocompression bonding step S3 is able to be performed while avoiding unwanted pressure bonding in a region that is not covered by a conductor foil on the upper surface of the uppermost second sheet 22. Therefore, it is easier to design the conductor foil of the second sheet 22. For example, preferred embodiments of the present invention are able to be applied even in the case in which the conductor foil of the second sheet 22 includes a pattern, such as a wiring pattern or a land pattern to mount an electronic component.

In both preferred embodiments 1 and 2, the main material of the third sheet 23 may preferably be the same or substantially the same as the main material used for the one or more second sheets 22. Consequently, the same or substantially the same expansion/contraction state is able to be achieved in the second sheet 22 and the third sheet 23 when the thermocompression bonding step S3 is performed. Thus, it is possible to reduce or prevent the generation of defects in the thermocompression bonding step S3 caused by differences in thermal expansion coefficient and other differences between the third sheet 23 and the second sheet 22.

### Preferred Embodiment 3

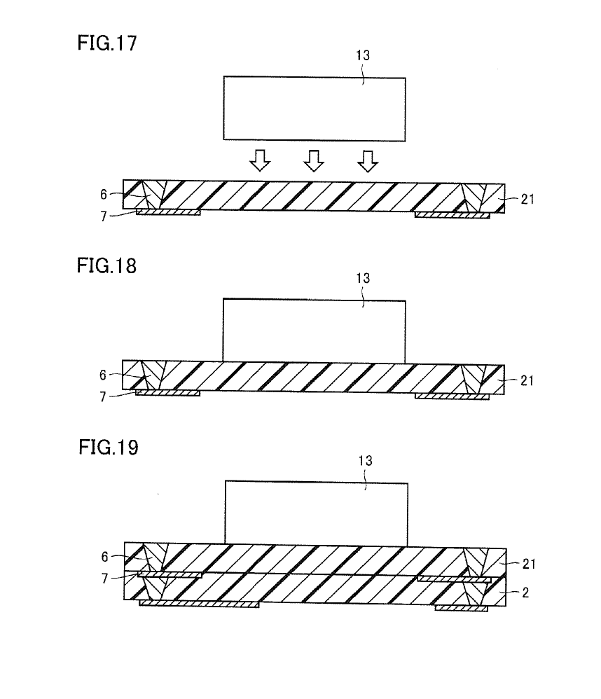

A resin multilayer substrate manufacturing method of preferred embodiment 3 of the present invention will be described with reference to FIGS. 17 to 22. The basic flow of the resin multilayer substrate manufacturing method of the present preferred embodiment is the same or substantially the same as that of the manufacturing method described in the preferred embodiment 1, but the manufacturing method of the present preferred embodiment differs with respect to the following points.

The resin multilayer substrate manufacturing method of the present preferred embodiment further includes a step of temporarily pressure bonding the block 13 to a surface of the first sheet 21, and in the step S2 of arranging one or more second sheets 22 on the upper surface of the first sheet 21, one or more second sheets 22 are arranged such that the block 13, which has been temporarily pressure bonded to the surface of the first sheet 21, enters the inside of the space 15.

The individual steps of the resin multilayer substrate manufacturing method of this preferred embodiment will be described in detail hereafter.

As illustrated in FIG. 17, a step of temporarily pressure bonding the block 13 to a surface of the first sheet 21 is performed. The block 13 may be positioned with respect to the first sheet 21 and temporarily pressure bonded to the first sheet 21 in a state of being affixed by an adhesive sheet, which is not illustrated. Either heat or pressure or both heat and pressure may be used to perform the temporary pressure bonding. The situation illustrated in FIG. 18 is achieved as a result of temporarily pressure bonding the block 13 to the surface of the first sheet 21.

The state illustrated in FIG. 19 is achieved by stacking a resin sheet 2 on a surface of the first sheet 21 that is on the opposite side from the surface of the first sheet 21 to which the block 13 is temporarily pressure bonded, and arranging the assembly such that the block 13 faces upward. Alternatively, the state illustrated in FIG. 19 is achieved by arranging the resin sheet 2 as illustrated in FIG. 2, and then arranging the first sheet 21 so as to be stacked on the upper surface of the resin sheet 2. A step of arranging the first sheet 21 in this manner is step S1. In contrast to preferred embodiment 1, in the present preferred embodiment, the block 13 has already been temporarily pressure bonded to the surface of the first sheet 21 when the first sheet 21 is arranged in step S1.

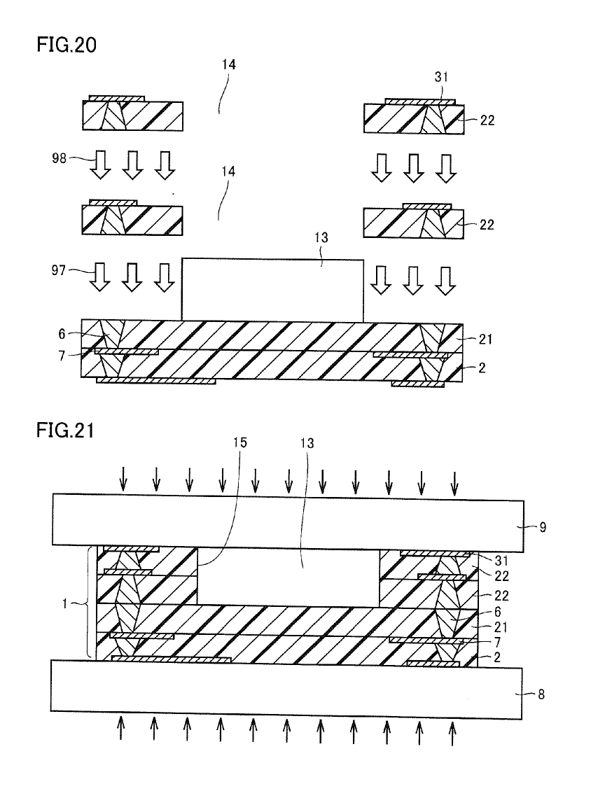

As the step S2, as illustrated in FIG. 20, one or more second sheets 22, which each include the first opening 14 and a thermoplastic resin as a main material, are arranged so as to be stacked on the first sheet 21.

As the thermocompression bonding step S3, heat and pressure are applied to the multilayer body 1, which is formed so as to include the first sheet 21 and the one or more second sheets 22, in a state in which the block 13, which has a higher rigidity than the thermoplastic resin, is located inside the space 15. This step is to integrate the multilayer body 1, and is also called a “permanent pressure bonding step”. In the thermocompression bonding step S3, for example, as illustrated in FIG. 21, the multilayer body 1 is sandwiched between the lower pressing plate 8 and the upper pressing plate 9 and is subjected to pressing while being heated. As a result, pressure bonding occurs at portions inside the multilayer body 1 at which thermoplastic resin portions contact each other, and substantially all of the portions of the multilayer body 1 are integrated with each other. In FIG. 21, the multilayer body 1 is directly sandwiched between the lower pressing plate 8 and the upper pressing plate 9, but cushioning material may instead be interposed between the lower pressing plate 8 and the multilayer body 1, between the upper pressing plate 9 and the multilayer body 1, or in both of these locations. In contrast to preferred embodiment 1, in the present preferred embodiment, the third sheet 23 is not used, and therefore the upper surface of the block 13 is exposed at the upper surface of the multilayer body 1.

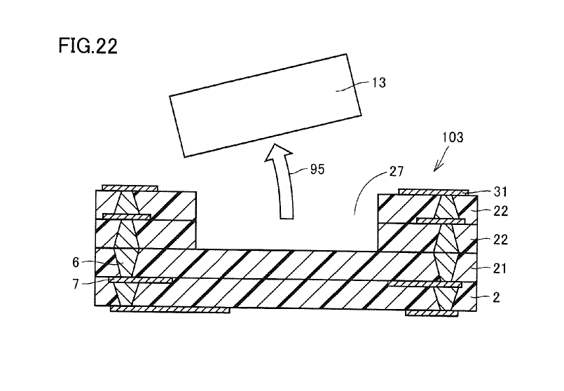

As the step S4, the block 13 is removed as illustrated in FIG. 22 after the thermocompression bonding step S3. Thus, a resin multilayer substrate 103 including a recess 27 is obtained. The details of the method of removing the block 13 in the step S4 are the same or substantially the same as described in preferred embodiment 1.

In the present preferred embodiment, since the thermocompression bonding step S3 is performed in a state in which the block 13, which has a higher rigidity than the thermoplastic resin, is located inside the space 15, heating and pressing is able to be normally performed, and the resin multilayer substrate 103 is able to be obtained in which a desired recess is appropriately provided. The metal molds used in the thermocompression bonding step S3 may be flat as illustrated by the lower pressing plate 8 and the upper pressing plate 9, and therefore, there is no need to prepare a large number of different metal molds to match the shape of the resin multilayer substrate 103. Therefore, a significant increase in cost is not incurred.

A product obtained in a manufacturing method according to any one of preferred embodiments 1 to 3 is a resin multilayer substrate, for example. In preferred embodiments 1 and 2, the third sheet 23 is used as a sheet to temporarily pressure bond the block 13. The third sheet 23 is later removed, and therefore does not remain in the product. Therefore, a portion retaining the thermal history from when the block was temporarily pressure bonded does not remain in the finished product, which is preferable.

In contrast, in preferred embodiment 3, the block 13 is temporarily pressure bonded to the first sheet 21 and the first sheet 21 remains as a portion of the finished product. Focusing on the first sheet 21, the first sheet 21 is heated two times, namely, when the temporary pressure bonding is performed and when the permanent pressure bonding is performed. The other sheets are only heated once, namely, when the permanent pressure bonding is performed, whereas the first sheet 21 experiences heating a greater number of times. In other words, the first sheet 21 has a different heat history from the other sheets. There is a possibility of the first sheet having a different contraction state from the other sheets due to the first sheet 21 having a different heat history from the other sheets. In the case in which there would be a problem due to the effect of such a difference in heat history, it would be preferable to use the manufacturing method of preferred embodiment 1 or 2, rather than the manufacturing method of preferred embodiment 3.

In all of the preferred embodiments, the main material of the first sheet 21 and the main material of the one or more second sheets 22 may preferably be the same as each other, for example.

Heretofore, for convenience of explanation, only a region corresponding to one resin multilayer substrate has been illustrated and described, but processing may instead be performed for a plurality of resin multilayer substrates in one batch in the form of a large-sized substrate that is an agglomeration of a plurality of resin multilayer substrates. In this case, for example, a plurality of blocks 13 may be simultaneously temporarily pressure bonded to the surface of a resin sheet in a desired arrangement by arranging a plurality of blocks 13 so that the blocks 13 have a desired positional relationship on one surface of a single adhesive sheet and then arranging the adhesive sheet, which is holding the blocks 13, so as to face the desired resin sheet, sticking the adhesive sheet to the resin sheet, and then performing heating and pressing as necessary in order to temporarily pressure bond the plurality of blocks 13 to the resin sheet, which is the first sheet or third sheet.

The block 13 may preferably include a metal as a main material, for example. The block 13 may instead include another material other than a metal as a main material. If we consider removal of the block 13 after the thermocompression bonding step, it is preferable that the main material of the block 13 be a material that is unlikely to become pressure bonded to the thermoplastic resin. Heretofore, the block 13 has been illustrated as having a rectangular or substantially rectangular parallelepiped shape, but the shape of the block 13 is not limited to a rectangular or substantially rectangular parallelepiped shape and the shape of the block 13 is not limited to a simple shape. The shape of the block 13 may include steps. The block 13 is not limited to having a rectangular or substantially rectangular shape when viewed from above. For example, an object obtained by forming a desired pattern in a metal plate may be used as the block 13.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A resin multilayer substrate manufacturing method comprising:
providing a first sheet that includes a thermoplastic resin as a main material;
providing one or more second sheets, which each include a first opening and a thermoplastic resin as a main material, so as to be stacked on the first sheet;
thermocompression bonding to apply heat and pressure to a multilayer body formed to include the first sheet and the one or more second sheets such that a block is inside a space formed by the first opening of one second sheet or by a series of first openings of two or more second sheets;
removing the block after the thermocompression bonding step;
temporarily pressure bonding the block to a surface of a third sheet;
after the providing the one or more second sheets to be stacked on the first sheet and prior to the thermocompression bonding step, stacking the third sheet on an upper side of the one or more second sheets such that the block, which has been temporarily pressure bonded to the third sheet, is below the third sheet and the block enters the space; and
removing the third sheet; wherein
when the providing the one or more second sheets so as to be stacked on the first sheet is complete, an upper surface of the second sheet that is uppermost among the one or more second sheets includes a first region that is covered by a first conductor foil; and
in the stacking the third sheet, at least a region of the third sheet that faces the first region is covered by a second conductor foil.

2. The resin multilayer substrate manufacturing method according to claim 1, wherein the second conductor foil includes a second opening, and the block includes a second region that is temporarily pressure bonded to the third sheet via the second opening and a third region that contacts the second foil around a periphery of the second opening.

3. The resin multilayer substrate manufacturing method according to claim 1, wherein in the stacking the third sheet, an upper surface of the second sheet that is uppermost among the one or more second sheets includes a fourth region that is not covered by a conductor foil and is exposed, and a recess or a through hole is formed in a region of the third sheet that faces the fourth region.

4. The resin multilayer substrate manufacturing method according to claim 1, wherein a main material of the third sheet is identical to a main material of the one or more second sheets.

5. The resin multilayer substrate manufacturing method according to claim 1, wherein the block has a higher rigidity than the thermoplastic resin.

6. The resin multilayer substrate manufacturing method according to claim 1, wherein the thermoplastic resin of the first sheet is a liquid crystal polymer or a thermoplastic polyimide.

7. A resin multilayer substrate manufacturing method comprising:
providing a first sheet that includes a thermoplastic resin as a main material;
providing one or more second sheets, which each include a first opening and a thermoplastic resin as a main material, so as to be stacked on the first sheet;
thermocompression bonding to apply heat and pressure to a multilayer body formed to include the first sheet and the one or more second sheets such that a block is inside a space formed by the first opening of one second sheet or by a series of first openings of two or more second sheets;
temporarily pressure bonding the block to a surface of the first sheet; and
removing the block after the thermocompression bonding step; wherein
in the providing the one or more second sheets on a surface of the first sheet, the one or more second sheets are provided such that the block, which has been temporarily pressure bonded to the surface of the first sheet, enters inside the space.

8. The resin multilayer substrate manufacturing method according to claim 7, wherein the block has a higher rigidity than the thermoplastic resin.

9. The resin multilayer substrate manufacturing method according to claim 7, wherein the thermoplastic resin of the first sheet is a liquid crystal polymer or a thermoplastic polyimide.

10. A resin multilayer substrate, comprising:
a first sheet including a thermoplastic resin defining a main material; and
one or more second sheets, which each include a first opening and a thermoplastic resin defining a main material, stacked on top of one another; wherein
the second sheet that is outermost among the one or more second sheets includes a conductor foil on an outside main surface; and
the first sheet includes a through hole in a region that is superposed with the first opening of the second sheet in plan view.

11. The resin multilayer substrate according to claim 10, wherein the thermoplastic resin of the first sheet is a liquid crystal polymer or a thermoplastic polyimide.
